(19) United States
(12) Patent Application Publication
(10) Pub. No.: US 2007/0248794 A1
(43) Pub. Date: Oct. 25, 2007

(54) Formation of high metallic content carbon nanotube structures

(76) Inventors: Florian Gstrein, Portland, OR (US); James M. Blackwell, Portland, OR (US); Amlan Majumdar, White Plains, NY (US); Valery M. Dubin, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/408,745

(22) Filed: Apr. 21, 2006

(51) Int. Cl. B05D 7/22; C23C 16/00; B32B 9/00; B32B 3/10

(52) U.S. Cl. 428/137; 427/230; 427/249.1; 977/742; 977/842; 428/698

(57) ABSTRACT

Methods and associated structures of forming a microelectronic device are described. Those methods may include forming an opening in a substrate, placing at least one multi-walled CNT within the opening, and forming a carbide layer on the at least one multi-walled CNT.

### BACKGROUND OF THE INVENTION

Multi-walled carbon nanotubes (CNTs) may possess semiconducting or metallic properties depending upon the chirality of the CNT. Metallic CNTs with 1-2 nm diameters may exhibit energy bandgaps within a range of about 0.8 to about 0.4 electron volts. Both electrons and holes are expected to have good transport properties within metallic CNT's, consequently metallic CNTs appear as attractive candidates for use as conductive interconnect structures, for example.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1h represent structures according to an embodiment of the present invention.

FIG. 2 represents structures according to an embodiment of the present invention.

FIG. 3 represents a system according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming a microelectronic structure, such as a CNT interconnect structure, are described. Those methods may comprise forming an opening in a substrate, placing at least one multi-walled CNT within the opening, and forming a carbide layer on the at least one multi-walled CNT. The methods of the present invention enable the formation of a low contact resistance, high packing density, high current carrying capacity CNT interconnect structure.

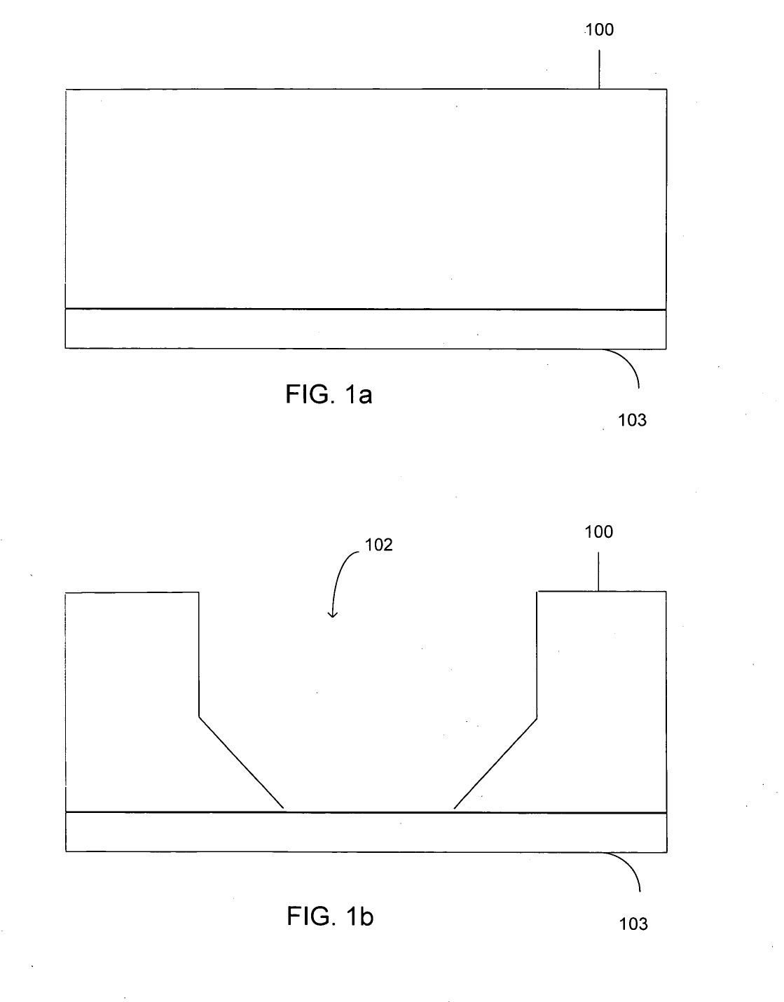

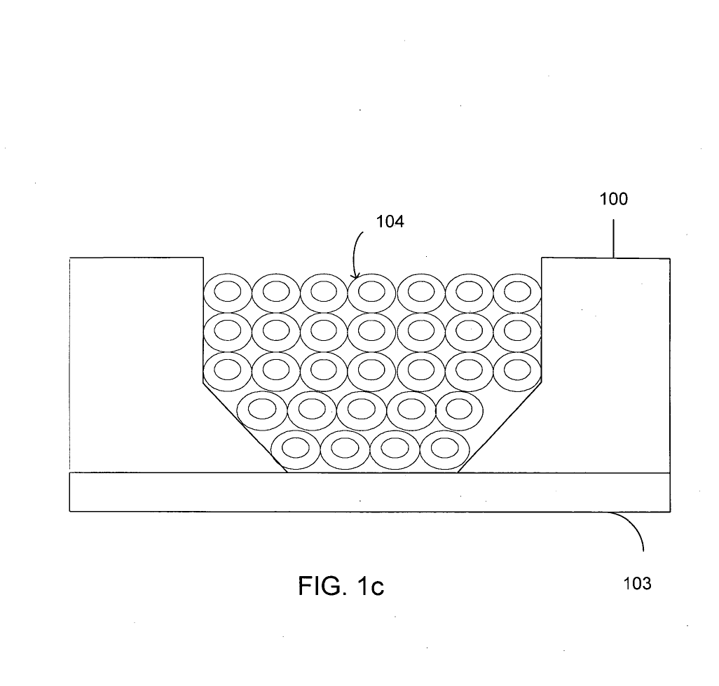

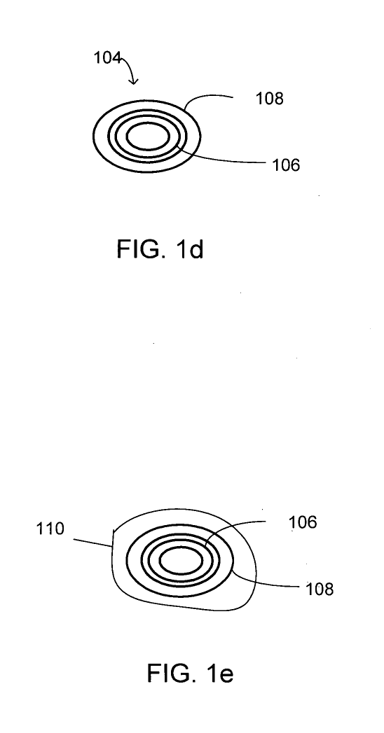

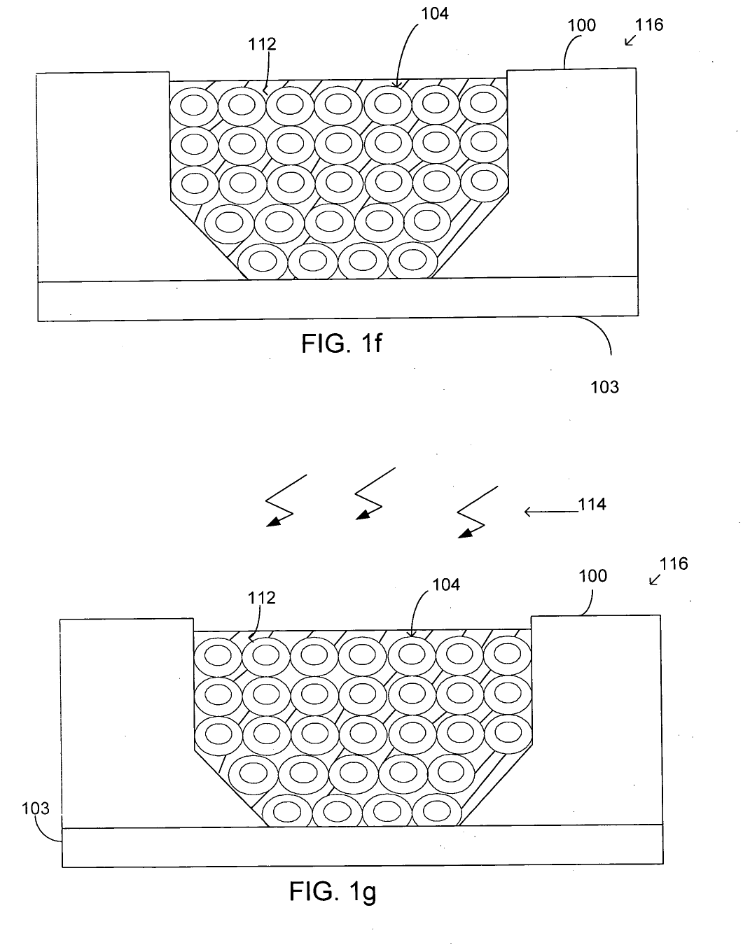

FIGS. 1a-1h illustrate a embodiments of a method and associated structures of forming a CNT interconnect structure. FIG. 1a illustrates a cross-section of a portion of a substrate 100. In one embodiment, the substrate 100 may comprise any type of material that may be used in the fabrication of a microelectronic device. In one embodiment, the substrate 100 may comprise a dielectric layer, such as but not limited to silicon dioxide, silicon nitride and silicon oxynitride, for example.

In one embodiment, the substrate 100 may comprise an interlayer dielectric (ILD) for example, as is well known in the art. In one embodiment, the substrate 100 may comprise a thickness of about 5,000 angstroms to about 3 microns, and may be formed by various deposition methods, such as chemical vapor deposition, is are well known in the art. In another embodiment, the substrate 100 may be formed as a layer of a phospho-silicate-glass (PSG), boron doped PSG (BPSG), silicon oxide glass (SOG), silicon dioxide, fluorine-doped silicon oxide, low dielectric constant (low-k) insulator, spin-on dielectric material, or the like. A low-k insulator may comprise a material having a dielectric constant lower than silicon dioxide.

In one embodiment, the substrate 100 may further comprise a semiconductor layer 103. The substrate 100 may be disposed on the semiconductor layer 103. In one embodiment, the semiconductor layer 103 may comprise a silicon layer. An opening 102 may be formed in the substrate 100 (FIG. 1b). In one embodiment, the opening 102 may comprise an opening of an interconnect structure, such as but not limited to a damascene interconnect structure, as is known in the art.

At least one multi-walled CNT 104 may be placed within the opening 102 (FIG. 1c). Although double walled CNT's are depicted within the opening 102, it will be understood that multi-walled CNTs may be incorporated within the various embodiments presented herein. The at least one multi-walled CNT nanotube 104 may be applied to the substrate 100 by utilizing any suitable application process, such as but not limited to a spin on process and/or a sonication process, as are well known in the art. In one embodiment, about 70 to about 90 percent of the at least one multi-walled CNT 104 may comprise metallic CNTs, as are known in the art. In another embodiment, the at least one multi-walled CNT 104 may be formed within the opening 102, utilizing any suitable formation process, such as, but not necessarily limited, to chemical vapor deposition (CVD), plasma assisted CVD, arc discharge, laser ablation, filling of single walled nanotubes (produced and deposited by any known method) with fullerenes such as bucky balls and subsequent annealing, which results in the formation of multiwalled carbon nanotubes, for example.

In one embodiment, the at least one multi-walled CNT 104 may comprise at least one double walled CNT (FIG. 1d), wherein the at least one double walled CNT may comprise an inner wall 106 and an outer wall 108. In one embodiment, about 60 to about 90 percent of the at least one double-walled CNT 104 may comprise metallic CNTs. Double walled CNTs may comprise an increased number of conductance channels, as compared with single walled CNT's. In one embodiment, double walled CNTs may comprise twice the number of conductance channels that single walled CNTs. For example, a double walled CNT may comprise 8 conductive channels, while a single walled CNT may comprise 4 conductive channels. Thus, in some cases, bundles of double walled CNTs may comprise a decreased line resistance as compared to bundles of single walled CNTs.

A carbide forming material 110 may be formed on the at least one multi-walled CNT 104 (FIG. 1e). In one embodiment, the carbide forming material 110 may be formed by at least one of physical vapor deposition (PVD), CVD and atomic layer deposition (ALD), by illustration and not limitation. In one embodiment, the carbide forming material 110 may comprise any such layer that may form a carbide with the at least one CNT 104.

The carbide forming material 110 may form a conformal layer over the at least one multi-walled CNT 104. In one embodiment, the carbide forming material 110 may comprise at least one of titanium, tungsten, titanium tungsten, molybdenum, niobium, vanadium, chromium, tantalum, zirconium and combinations thereof. In one embodiment, the carbide forming material 110 may chemically react and/or form a physical bond with the at least one multi-walled CNT 104 to form a carbide layer 112 on the at least one multi-walled CNT 104 (FIG. 1f). For example, the carbide forming material 110 may interdiffuse within the at least one multi-walled CNT 104, to form the carbide layer 112. The electronic coupling between the at least one multi-walled CNT and the carbide forming material 110 may lower the contact resistance of the structure. Also, since the carbide forming material 110 may be very reactive with the at least one multi-walled CNT 104, formation of a the carbide layer 112 may lower the contact resistance.

In one embodiment, a contact area may be formed, wherein the contact area may comprise the carbide layer 112 disposed on at least a portion of the at least one multi-walled CNT 104. In one embodiment, the contact area may comprise a conductive contact of a CNT device, for example, or in another embodiment may comprise a portion of an interconnect structure of a device. By forming the carbide layer 112 on a portion of the plurality of multi-walled CNT's, the contact resistance of the contact area may be significantly lowered. In some cases, the contact resistance of an interconnect structure utilizing such a contact area may be less than about 30 Kohms. In another embodiment, the contact resistance of an interconnect structure utilizing such a contact area may correspond to the lowest contact resistance of an individual single-walled carbon nanotube, which in some cases may comprise a quantum resistance of about 6.8 kOhm

The carbide layer 112 may improve the electronic coupling between the inner and outer walls 106, 108 of the at least one multi-walled CNT 104 as compared with other materials, such as metals, when in Van-der-Waals contact. Other materials, such as Palladium, known to form good contacts to single-walled tubes, tend to rely on electron tunneling to address lower-lying shells. Hence the contact resistance may be much higher as compared with contacts formed according to various embodiments of the present invention.

A CNT interconnect structure 116 may be formed by forming the carbide layer 112 on the at least one multi-walled CNT 104. The CNT interconnect structure 116 may be annealed 114 to further lower the contact resistance of the CNT interconnect structure 116 (FIG. 1g). The CNT interconnect structure 116 may comprise a high metallic CNT content, and may comprise a high packing density of multi-walled CNT bundles within the interconnect structure. Such a CNT interconnect structure 116 may comprise extremely low DC line resistance.

A metal layer 118 may be formed on the contact area of the at least one multi-walled CNT 104 (FIG. 1h). The metal layer 118 may comprise metallic materials that comprise good electromigration properties and a low resistivity. Such metals may include, but are not limited to, palladium, platinum, ruthenium, gold, copper, and may be deposited by any known method. In some embodiments the metal layer 118 may serve to stitch segments of multi-walled CNT bundles together and/or to provide short lengthed vias, as are known in the art.

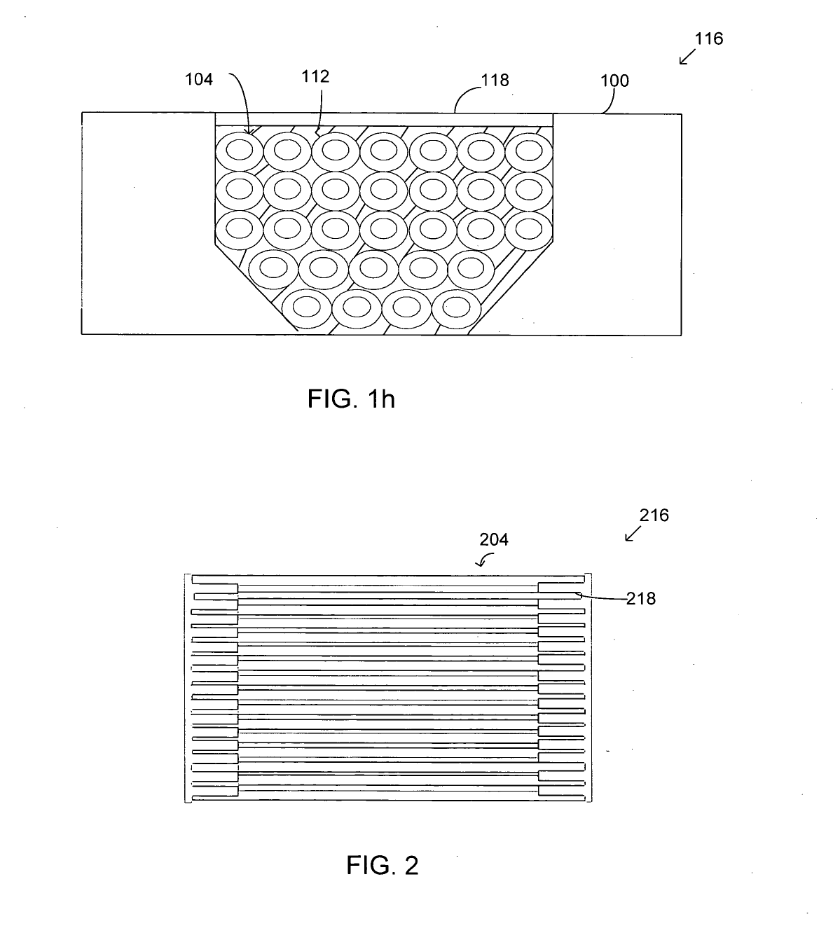

FIG. 2 depicts a top view of another embodiment of the present invention. A CNT interconnect structure 216 may comprise a contact area 218, that may comprise a carbide layer, similar to the carbide layer of FIG. 1h, for example. The carbide layer may be disposed on a portion of at least one multi-walled CNT 204. The carbide layer may also comprise a metal layer, similar to the metal layer of FIG. 1h, for example.

Thus, the embodiments of the present invention enable a CNT interconnect structure that comprises low contact resistance, high packing density (as compared with single walled CNT interconnect structures, for example), and increased current carrying capacity.

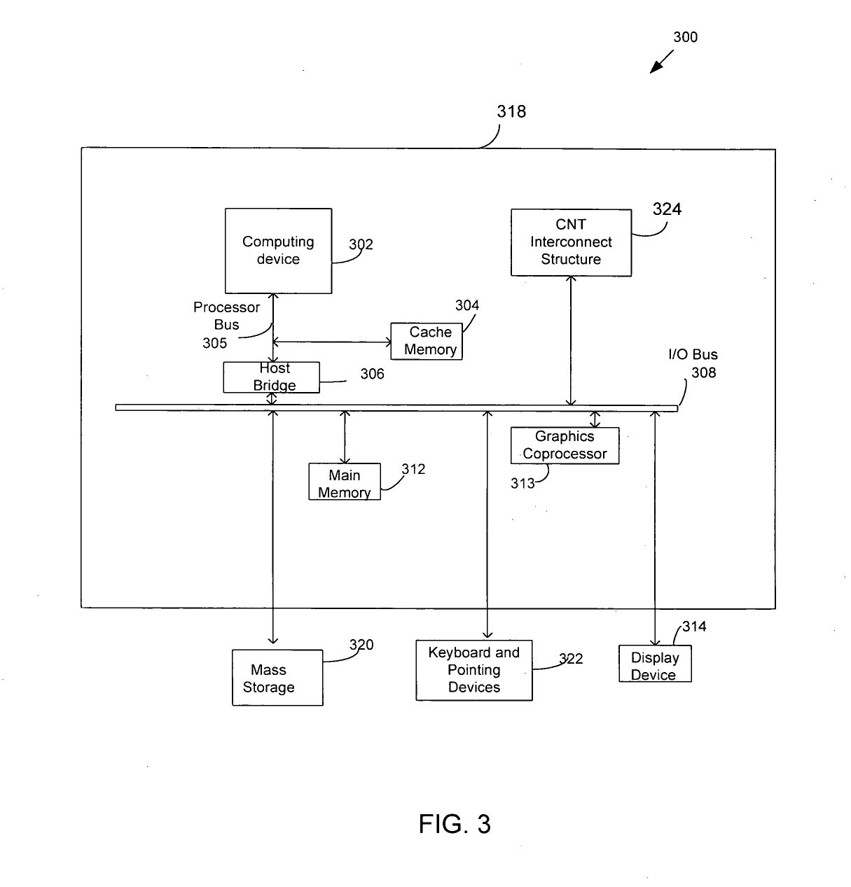

FIG. 3 is a diagram illustrating an exemplary system 300 capable of being operated with methods for fabricating a microelectronic structure, such as the CNT interconnect structure of FIG. 1e, for example. It will be understood that the present embodiment is but one of many possible systems in which the substrate core structures of the present invention may be used.

In the system 300, the CNT interconnect structure 324 may be communicatively coupled to a printed circuit board (PCB) 318 by way of an I/O bus 308. The communicative coupling of the CNT interconnect structure 324 may be established by physical means, such as through the use of a package and/or a socket connection to mount the CNT interconnect structure 324 to the PCB 318 (for example by the use of a chip package, interposer and/or a land grid array socket). The CNT interconnect structure 324 may also be communicatively coupled to the PCB 318 through various wireless means (for example, without the use of a physical connection to the PCB), as are well known in the art.

The system 300 may include a computing device 302, such as a processor, and a cache memory 304 communicatively coupled to each other through a processor bus 305. In one embodiment, the computing device 302 may comprise at least one CNT interconnect structure, similar to the CNT structure of FIG. 1h, for example. The processor bus 305 and the I/O bus 308 may be bridged by a host bridge 306. Communicatively coupled to the I/O bus 308 and also to the CNT interconnect structure 324 may be a main memory 312. Examples of the main memory 312 may include, but are not limited to, static random access memory (SRAM) and/or dynamic random access memory (DRAM), and/or some other state preserving mediums. In one embodiment, the main memory 312 may comprise at least one CNT interconnect structure. The system 300 may also include a graphics coprocessor 313, however incorporation of the graphics coprocessor 313 into the system 300 is not necessary to the operation of the system 300. Coupled to the I/O bus 308 may also, for example, be a display device 314, a mass storage device 320, and keyboard and pointing devices 322.

These elements perform their conventional functions well known in the art. In particular, mass storage 320 may be used to provide long-term storage for the executable instructions for a method for forming and/or utilizing CNT structures in accordance with embodiments of the present invention, whereas main memory 312 may be used to store on a shorter term basis the executable instructions of a method for forming and/or utilizing CNT interconnect structures in accordance with embodiments of the present invention during execution by computing device 302. In addition, the instructions may be stored, or otherwise associated with, machine accessible mediums communicatively coupled with the system, such as compact disk read only memories (CD-ROMs), digital versatile disks (DVDs), and floppy disks, carrier waves, and/or other propagated signals, for example. In one embodiment, main memory 312 may supply the computing device 302 (which may be a processor, for example) with the executable instructions for execution.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that certain aspects of microelectronic devices, such as a FET, are well known in the art. Therefore, it is appreciated that the Figures provided herein illustrate only portions of an exemplary microelectronic device that pertains to the practice of the present invention. Thus the present invention is not limited to the structures described herein.

What is claimed is:

1. A method comprising:
forming an opening in a substrate;
placing at least on multi-walled CNT within the opening; and
forming a carbide layer on the at least one multi-walled CNT.

2. The method of claim 1 wherein forming the carbide layer comprises forming a carbide forming material on the at least one multi-walled CNT, wherein the carbide forming material reacts with the at least one multi-walled CNT to form a carbide layer on the at least one multi-walled CNT.

3. The method of claim 2 wherein forming a carbide forming material comprises forming at least one of titanium, tungsten, titanium tungsten, molybdenum, niobium, vanadium, chromium, tantalum, zirconium, and combinations thereof and combinations thereof.

4. The method of claim 2 further comprising annealing the carbide forming material and the at least one multi-walled CNT.

5. The method of claim 1 wherein placing the at least one multi-walled CNT within the opening further comprises wherein at least about 60 percent of the at least one multi-walled CNT are metallic CNTs.

6. The method of claim 1 further comprising forming a metal layer on the carbide layer, wherein the metal layer comprises at least one of gold, palladium, ruthenium, copper and platinum.

7. The method of claim 1 wherein forming the carbide layer comprises forming the carbide layer by at least one of PVD, iPVD and ALD.

8. The method of claim 1 wherein forming the at least one multi-walled CNT comprises forming at least one double walled CNT.

9. The method of claim 8 further comprising wherein approximately each of the at least one double walled CNT comprises about 8 channels of conductance.

10. The method of claim 1 wherein placing the at least one multi-walled CNT comprises placing the at least on multi-walled CNT by at least one of a spin on process and a sonication process.

11. A method of forming an interconnect structure comprising:
placing a plurality of multi-walled CNT's within an opening in a substrate;
forming a contact area by forming a carbide forming material on a portion of the plurality of multi-walled CNT's; and
forming a metal layer on the contact area.

12. The method of claim 11 wherein forming a carbide forming material further comprises wherein the carbide forming material forms a carbide layer on the contact area of the plurality of multi-walled CNTs.

13. The method of claim 11 further comprising wherein the contact area comprises a contact resistance of less than about 30 Kohms.

14. The method of claim 11 further comprising annealing the contact area to lower the contact resistance.

15. A structure comprising:
a plurality of multi-walled CNTs disposed within an opening of a substrate; and
a carbide forming material disposed on a contact area of the plurality of multi-walled CNTs.

16. The structure of claim 15 wherein the carbide forming material disposed on the contact area of the plurality of multi-walled CNTs comprises a conductive contact of a CNT device.

17. The structure of claim 16 wherein the conductive contact comprises a contact resistance of less than about 30 Kohms.

18. The structure of claim 15 wherein the plurality of multi-walled CNTs comprises a plurality of double walled CNTs.

19. The structure of claim 15 wherein the plurality of multi-walled CNTs comprises between about 60 to about 90 percent metallic CNTs.

20. The structure of claim 15 wherein the carbide forming material comprises at least one of titanium, tungsten, molybdenum, niobium, vanadium, chromium, tantalum, zirconium, and combinations thereof and combinations thereof.

21. The structure of claim 15 further comprising a metal layer disposed on the carbide forming material.

22. The structure of claim 21 wherein the metal layer comprises at least one of gold, palladium, ruthenium, copper and platinum.

23. The structure of claim 15 wherein the structure comprises a CNT interconnect structure.

24. The structure of claim 23 further comprising a system comprising:
a bus communicatively coupled to the CNT interconnect structure; and
a DRAM communicatively coupled to the bus.

25. The system of claim 24 wherein the carbide forming material comprises at least one of tungsten, titanium, molybdenum, niobium, vanadium, chromium, tantalum, zirconium, and combinations thereof and combinations thereof.

26. The system of claim 24 wherein the plurality of multi-walled CNTs comprises a plurality of double walled CNTs.

27. The system of claim 24 wherein the contact area comprises a metal contact comprising a contact resistance of less than about 30 Kohms.
